(19) United States
(12) Patent Application Publication
(10) Pub. No.: US 2004/0059973 A1
(43) Pub. Date: Mar. 25, 2004

(54) Apparatus for testing a device under test using a high speed bus and method therefor

(76) Inventors: Brent M. Sherman, Phoenix, AZ (US); Joshua J. Earl, Mesa, AZ (US); Brian D. Redger, Tempe, AZ (US)

Correspondence Address: BLAKELY SOKOLOFF TAYLOR & ZAFMAN, 12400 WILSHIRE BOULEVARD, SEVENTH FLOOR, LOS ANGELES, CA, 90025, US

(21) Appl. No.: 10/254,748

(22) Filed: Sep. 24, 2002

(51) Int. Cl. G01R 31/317

(52) U.S. Cl. 714/724

(57) ABSTRACT

Briefly, in accordance with one embodiment of the invention, a system includes a device under test (DUT) having a joint test access group (JTAG) port. The JTAG port may be accessed with a high speed and an integrated circuit adapted to access the JTAG port of the DUT.

### BACKGROUND

The Institute of Electrical and Electronics Engineers (IEEE) Standard 1149.1 relates to techniques whereby integrated circuits may be tested by incorporating software-controlled hardware into the integrated circuit during manufacturing. Because the group of key electronic companies was known as the Joint Test Action Group, the terms “IEEE Standard 1149.1” and “JTAG Standard” often are used interchangeably.

Per the JTAG Standard, at least portions of an integrated circuit may be accessed and tested through JTAG circuitry and/or a JTAG port. In a testing or debugging environment, a host or testing processor may send instructions and receive and/or transmit data to a device under test (DUT). These signals are conventionally sent using a cable (e.g. a parallel port cable or a RS-232 cable). Due to limitations associated with the cable, the rate at which data may be sent to the DUT may be limited to less than about 100 kilobytes per second.

Thus, there is a continuing need for better ways to transfer or receive data to devices under test from a host or testing processor.

### BRIEF DESCRIPTION OF THE DRAWING

The subject matter regarded as the invention is particularly pointed out and distinctly claimed in the concluding portion of the specification. The invention, however, both as to organization and method of operation, together with objects, features, and advantages thereof, may best be understood by reference to the following detailed description when read with the accompanying drawing in which:

the figure is a schematic representation of an embodiment of the present invention.

It will be appreciated that for simplicity and clarity of illustration, elements illustrated in the figure have not necessarily been drawn to scale.

### DETAILED DESCRIPTION

In the following detailed description, numerous specific details are set forth in order to provide a thorough understanding of the invention. However, it will be understood by those skilled in the art that the present invention may be practiced without these specific details. In other instances, well-known methods, procedures, components and circuits have not been described in detail so as not to obscure the present invention.

Unless specifically stated otherwise, as apparent from the following discussions, it is appreciated that throughout the specification discussions utilizing terms such as “processing,” “computing,” “calculating,” “determining,” or the like, refer to the action and/or processes of a computer or computing system, or similar electronic computing device, that manipulate and/or transform data represented as physical, such as electronic, quantities within the computing system's registers and/or memories into other data similarly represented as physical quantities within the computing system's memories, registers or other such information storage, transmission or display devices.

Embodiments of the present invention may include apparatuses for performing the operations herein. This apparatus may be specially constructed for the desired purposes, or it may comprise a general purpose computing device selectively activated or reconfigured by a program stored in the device. Such a program may be stored on a storage medium, such as, but is not limited to, any type of disk including floppy disks, optical disks, CD-ROMs, magnetic-optical disks, read-only memories (ROMs), random access memories (RAMs), electrically programmable read-only memories (EPROMs), electrically erasable and programmable read only memories (EEPROMs), magnetic or optical cards, or any other type of media suitable for storing electronic instructions, and capable of being coupled to a system bus for a computing device.

The processes and displays presented herein are not inherently related to any particular computing device or other apparatus. Various general purpose systems may be used with programs in accordance with the teachings herein, or it may prove convenient to construct a more specialized apparatus to perform the desired method. The desired structure for a variety of these systems will appear from the description below. In addition, embodiments of the present invention are not described with reference to any particular programming language. It will be appreciated that a variety of programming languages may be used to implement the teachings of the invention as described herein.

In the following description and claims, the terms “coupled” and “connected,” along with their derivatives, may be used. It should be understood that these terms are not intended as synonyms for each other. Rather, in particular embodiments, “connected” may be used to indicate that two or more elements are in direct physical or electrical contact with each other. “Coupled” may mean that two or more elements are in direct physical or electrical contact. However, “coupled” may also mean that two or more elements are not in direct contact with each other, but yet still co-operate or interact with each other.

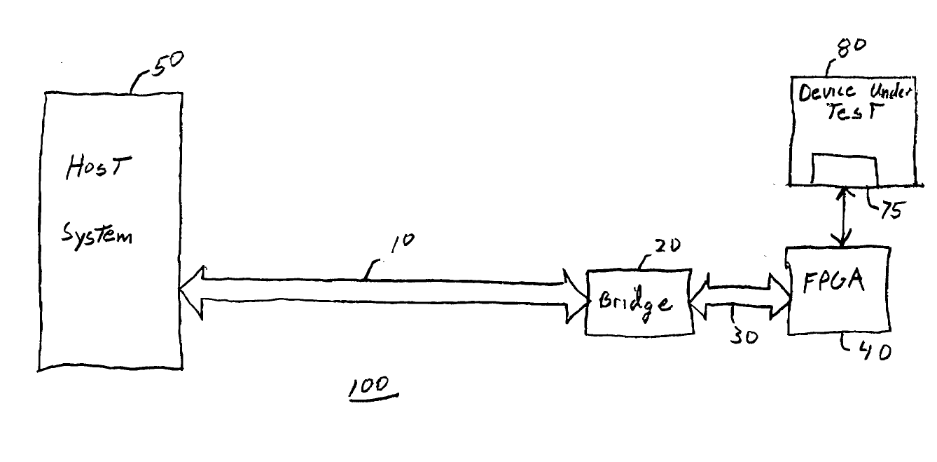

Turning to FIG. 1, an embodiment 100 in accordance with the present invention is described. Embodiment 100 may comprise a host system 50, such as, for example, a tester, a debugger, an emulation board, etc., although the scope of the present invention is not limited in this respect. In this particular embodiment, host system 50 may access a JTAG 75 port of a device under test (DUT) 80 via a high speed bus 10, a bridge 20, and a field programmable gate array (FPGA) 40.

Although the scope of the present invention is not limited in this respect, JTAG port 75 of DUT 80 may comprise four or more pins, any one of which may be referred to as a “boundary pin” or a “test access pin.” For example, JTAG port 75 may comprise a test clock (TCK) pin that receives a test clock signal for DUT 80, a test mode select (TMS) pin to select particular test modes, a test data in (TDI) pin to accept data into DUT 80, and/or a test data output (TDO) pin to send data out from DUT 80.

JTAG port 75 of DUT 80 may be accessed (e.g. written to, read from, polled, etc.) with another integrated circuit. In the particular embodiment show in the figure, FPGA 40 may be used, although the scope of the present invention is not limited in this respect. In alternative embodiments a processor, microcontroller, or other device may be used. The use of FPGA 40 may be a desirable lower cost solution. FPGA 40 may comprise registers and/or output pins that are directly connected to the appropriate pins of JTAG 75. FPGA 40 may optionally comprise a processor and/or state machine that may provide DUT 80 instructions and/or data through JTAG port 75, although the scope of the present invention is not limited in this respect.

As explained below, host system 50 may access JTAG port 75 of DUT 80 over bus 10, bridge 20, and local bus 30. Although the scope of the present invention is not limited in this respect, bus 10 may comprise a Peripheral Component Interconnect (PCI) bus as described in the “PCI Local Bus Specification, revision 2.2” set forth by the PCI Special Interest Group (SIG) on Dec. 18, 1998. In alternative embodiments, bus 10 may comprise an Industry Standard Architecture (ISA) bus, an Expanded Industry Standard Architecture (EISA) bus, a Universal Serial Bus (USB), a Universal Serial Bus II (USB2) bus, or a PCI-64 bit bus, although the scope of the present invention is not limited by the particular standard of specification with which bus 10 is compliant.

For example, although the scope of the present invention is not limited in this respect, bus 10 may have a transmission rate of at least 300 kilobytes per second.

If bus 10 is a PCI bus, it may be able to transfer or receive data at a much higher data rate than is associated with physical cables (i.e. about 150 kilobytes per second). For example, as PCI bus, bus 10 may have a transmission rate or throughput of at least 10 megabytes per second. By using a bus in accordance with one of the other specifications listed above, bus 10 may be chosen to have different transmission rates, such as, for example, about 1 megabyte per second or higher.

As shown in the figure, bus 10 may connect host system 50 to a bridge 20. Bridge 20 may optionally be used to interface and buffer transfers of data between DUT 10 and host system 50. Examples of such bridges may include PCI-PCI bridges as described in detail in the “PCI-PCI Bridge Architecture Specification, revision 1.1” set forth by the PCI Special Interest Group (SIG) on Apr. 5, 1995. Bridge 20 may provide data and/or instructions to FPGA 40 via a local bus 30. Bus 30 may comprise any one or more of the buses described above. Bus 30 may allow FPGA 40 to provide data to host system 10. It should be understood however, that the use of bus 30 and bridge 20 should be considered optional and may offer an advantage of testing, debugging, or accessing multiple devices under test (not shown).

In this particular embodiment, FPGA 40 may comprise logic or a register used to write information to JTAG port 75 and/or read the data from DUT 80. For example, FPGA 40 may store instructions and data to be provided to DUT 80 and/or may provide instructions and data from host system 10. Some of these instructions may be used to interrupt or halt the operation of DUT 80 so that its current state may be diagnosed. Thus, host system 10 may be able to test or debug the operation of DUT 80.

It should be understand that the scope of the present invention is not limited to the use of FPGA's to access the JTAG port of a DUT. In alternative embodiments, other logic devices may be used. In addition, in other embodiments of the present invention it may be desirable to have bus 10 connected directly to FPGA 40 or even to DUT 80 as the use of bridge 20 and local bus 30 should be considered optional.

While certain features of the invention have been illustrated and described herein, many modifications, substitutions, changes, and equivalents will now occur to those skilled in the art. It is, therefore, to be understood that the appended claims are intended to cover all such modifications and changes as fall within the true spirit of the invention.

1. A method comprising:
accessing a joint test access group (JTAG) port of a first integrated circuit by reading data from a second integrated circuit over a bus having a transmission rate of at least 300 kilobytes per second.

2. The method of claim 1 further comprising reading the data from a register in the second integrated circuit.

3. The method of claim 1, wherein reading data from a second integrated circuit includes reading data from a field programmable gate array.

4. The method of claim 1, wherein accessing the JTAG port of the first integrated circuit includes accessing the JTAG port over a Peripheral Components Interface (PCI) bus.

5. The method of claim 4, wherein accessing the JTAG port of the first integrated circuit includes accessing the second integrated circuit over a PCI to local bus bridge.

6. The method of claim 1, wherein accessing the JTAG port includes reading data from the second integrated circuit over a bus having a transmission rate of at least 10 megabytes per second.

7. The method of claim 1, wherein accessing the JTAG port of the first integrated circuit includes accessing the JTAG port over a Universal Serial Bus (USB).

8. The method of claim 1, further comprising writing data to the second integrated circuit over the bus.

9. An apparatus comprising:
a first integrated circuit having a joint test access group (JTAG) port;
a second integrated circuit having four output pins coupled to the JTAG port of the first integrated circuit; and
a bus coupled to the second integrated circuit, wherein the second integrated circuit is accessible at over the bus with a data rate of at least ten mega-bits per second.

10. The apparatus of claim 9, wherein the bus is a Peripheral Components Interface (PCI) bus.

11. The apparatus of claim 9, further comprising a bridge to couple the PCI bus to the second integrated circuit.

12. The apparatus of claim 11, wherein the second integrated circuit is coupled to the bridge with a local bus.

13. The apparatus of claim 9, wherein the second integrated circuit comprises a register to store data from the JTAG port.

14. The apparatus of claim 9, wherein the second integrated circuit comprises a field programmable gate array.

15. The apparatus of claim 9, further comprising a third integrated circuit coupled to the second integrated circuit over the bus.

16. The apparatus of claim 1 5, wherein the third integrated circuit is adapted to provide instructions to the first integrated circuit.

17. A method comprising:
providing an instruction from a host processor to a first integrated circuit over a high speed bus; and
accessing a joint test access group (JTAG) port of a device under test with the first integrated circuit.

18. The method of claim 17, wherein providing the instruction from the host processor to the first integrated circuit includes providing an instruction over a Peripheral Components Interface (PCI) bus.

19. The method of claim 17, further comprising providing the instruction to a bridge coupled to the first integrated circuit.

20. The method of claim 17, wherein providing the instruction includes providing an instruction to halt the operation of the DUT.
